(19) United States
(12) Patent Application Publication
(10) Pub. No.: US 2025/0063871 A1
(43) Pub. Date: Feb. 20, 2025

(54) DISPLAY DEVICE

(71) Applicant: Samsung Display Co., LTD., Yongin-si (KR)

(72) Inventors: WONTAE KIM, Yongin-si (KR); WOOJUNG JUNG, Yongin-si (KR)

(21) Appl. No.: 18/591,094

(22) Filed: Feb. 29, 2024

(30) Foreign Application Priority Data
Aug. 18, 2023 (KR) 10-2023-0108168

(51) Int. Cl. H01L 33/62

(52) U.S. Cl. CPC H01L 33/62

(57) ABSTRACT

A display device includes a display panel that displays images, a printed circuit board that drives the display panel and that is disposed in a first direction relative to the display panel, a connecting film electrically connecting the display panel and the printed circuit board, connection pads disposed at one end of the connection film and bonded to the display panel along a second direction intersecting the first direction and first signal pads disposed on the display panel along the second direction, transmitting a power voltage, and each overlapping on a plane with at least two of the connection pads.

This application claims priority to Korean Patent Application No. 10-2023-0108168, filed on Aug. 18, 2023, and all the benefits accruing therefrom under 35 U.S.C. § 119, the content of which in its entirety is herein incorporated by reference.

### BACKGROUND

### 1. Field

The invention generally relates to a display, and more particularly, to a display which provides visual information.

### 2. Description of the Related Art

A display device includes a display panel that displays an image, a printed circuit board (PCB) that drives the display panel, and a connecting film that connects the display panel and the printed circuit board. The display panel and the connection film have a pad where they are joined to each other to exchange power voltage.

### SUMMARY

Embodiments provide a display device with improved display quality.

A display device, according to embodiments may include a display panel that displays images, a printed circuit board driving the display panel and disposed in a first direction relative to the display panel, a connecting film electrically connecting the display panel and the printed circuit board, connection pads disposed at one end of the connection film bonded to the display panel and directed along a second direction intersecting the first direction and first signal pads disposed on the display panel and directed along the second direction, transmitting a power voltage, and overlapping with at least two of the connection pads on a plane.

In an embodiment, a planar area of each of the first signal pads may be larger than a planar area of each of the connection pads.

In an embodiment, each of the first signal pads may include a first side having a first inclination angle on a plane with respect to a reference line directed in the second direction, and a second side facing the first side and having a second inclination angle on a plane with respect to the reference line, which is different from the first inclination angle.

In an embodiment, each of the first signal pads may further include a third side connecting the first side and the second side and having a first length and a fourth side facing the third side and being disposed closer to the printed circuit board than the third side and having a second length which is different from the first length.

In an embodiment, a width of each of the first signal pads directed in the second direction may change from the third side to the fourth side.

In an embodiment, the second inclination angle may be larger than the first inclination angle, and the first length may be longer than the second length.

In an embodiment, a width of each of the first signal pads in the second direction may decrease from the third side to the fourth side.

In an embodiment, the second inclination angle may be smaller than the first inclination angle, and the first length may be shorter than the second length.

In an embodiment, a width of each of the first signal pads directed in the second direction may increase from the third side to the fourth side.

In an embodiment, the display device may further include second signal pads disposed on the display panel to be directed along the second direction, transmitting a data voltage, and overlapping with one of the connection pads on a plane, where each of the second signal pads may include a fifth side having a third inclination angle on a plane with respect to the reference line, a sixth side facing the fifth side and having a fourth inclination angle which is the same as the third inclination angle on a plane with respect to the reference line, a seventh side connecting the fifth side and the sixth side and having a third length, and an eighth side facing the seventh side to be disposed closer to the printed circuit board than the seventh side, and having a fourth length which is the same as the third length.

In an embodiment, a width of each of the second signal pads directed in the second direction may be constant from the seventh side to the eighth side.

In an embodiment, a planar area of each of the first signal pads may be larger than a planar area of each of the second signal pads.

In an embodiment, the second signal pads may overlap the connection pads in a one-to-one correspondence.

In an embodiment, one or more of the connection pads corresponding to one of the first signal pads may partially overlap the one of the first signal pads on a plane.

In an embodiment, the connection pads corresponding to one of the first signal pads may entirely overlap the one of the first signal pads on a plane.

A display device, according to an embodiment, may include a display panel that displays images and first signal pads disposed on the display panel and directed along one direction and transmitting a power voltage, where each of the first signal pads may include a first side having a first inclination angle on a plane with respect to a reference line directed in the one direction and a second side facing the first side and having a second inclination angle on a plane with respect to the reference line, and the second inclination angle is different than the first inclination angle.

In an embodiment, each of the first signal pads may further include a third side connecting the first side and the second side and having a first length and a fourth side facing the third side and being disposed closer to the printed circuit board than the third side, and including a second length which is different from the first length.

In an embodiment, a width of each of the first signal pads directed in the one direction may vary from the third side to the fourth side.

In an embodiment, a width of each of the first signal pads directed in the one direction may decrease from the third side to the fourth side.

In an embodiment, a width of each of the first signal pads directed in the one direction may increase from the third side to the fourth side.

In an embodiment, each of the signal pads has opposing first and second sides that have different tilt angles on a plane, and thus connect the first side and the second side and are directed to face each other. The lengths of the third side and the fourth side may be different from each other. Accordingly, the area on the plane of each of the signal pads may be larger than the area on the plane of each of the connection pads. Accordingly, each of the signal pads may overlap at least two of the connection pads on a plane. That is, the contact area between the connection pads and the signal pads may increase.

In an embodiment, the resistance difference between the connection pads and the signal pads can be reduced. Accordingly, heat generation of the display device can be reduced or prevented. Additionally, alignment error between the connection pads and the signal pads can be reduced. Accordingly, the reliability of the display device can be improved.

### BRIEF DESCRIPTION OF THE DRAWINGS

Illustrative, non-limiting embodiments will be more clearly understood from the following detailed description taken in conjunction with the accompanying drawings.

FIG. 1 is a plan view showing a display device, according to an embodiment.

FIG. 2 is a plan view showing connection pads arranged in area A of FIG. 1, according to an embodiment.

FIG. 3 is a plan view showing an example of signal pads arranged in area A of FIG. 1, according to an embodiment.

FIG. 4 is a plan view showing another example of signal pads arranged in area A of FIG. 1, according to an embodiment.

FIG. 5 is a plan view showing still another example of signal pads arranged in area A of FIG. 1, according to an embodiment.

FIG. 6 is a plan view showing the connection pads of FIG. 2 and the signal pads of FIG. 3 overlapping in area A of FIG. 1, according to an embodiment.

FIG. 7 is an enlarged plan view of a first signal pad included in the signal pads of FIG. 3, according to an embodiment.

FIG. 8 is an enlarged plan view of a second signal pad included in the signal pads of FIG. 3, according to an embodiment.

FIG. 9 is an enlarged plan view of a second signal pad included in the signal pads of FIG. 5, according to an embodiment.

FIG. 10 is a plan view showing still another example of signal pads arranged in area A of FIG. 1, according to an embodiment.

FIG. 11 is a plan view showing the connection pads of FIG. 2 and the signal pads of FIG. 10 overlapping in area A of FIG. 1, according to an embodiment.

FIG. 12 is an enlarged plan view showing the first signal pad included in the signal pads of FIG. 10, according to an embodiment.

FIG. 13 is a plan view showing signal pads arranged in area B of FIG. 1, according to an embodiment.

### DETAILED DESCRIPTION

Hereinafter, a display device according to embodiments will be described in more detail with reference to the accompanying drawings. The same or similar reference numerals will be used for the same elements in the accompanying drawings. The invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element (or a region, a layer, a portion, or the like) is referred to as being related to another such as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the invention. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms are relative concepts and are described on the basis of the directions indicated in the drawings.

It will be further understood that the terms “comprise”, “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof. As used herein, being “disposed directly on” may mean that there is no additional layer, film, region, plate, or the like between a part and another part such as a layer, a film, a region, a plate, or the like. For example, being “disposed directly on” may mean that two layers or two members are disposed without using an additional member such as an adhesive member, therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

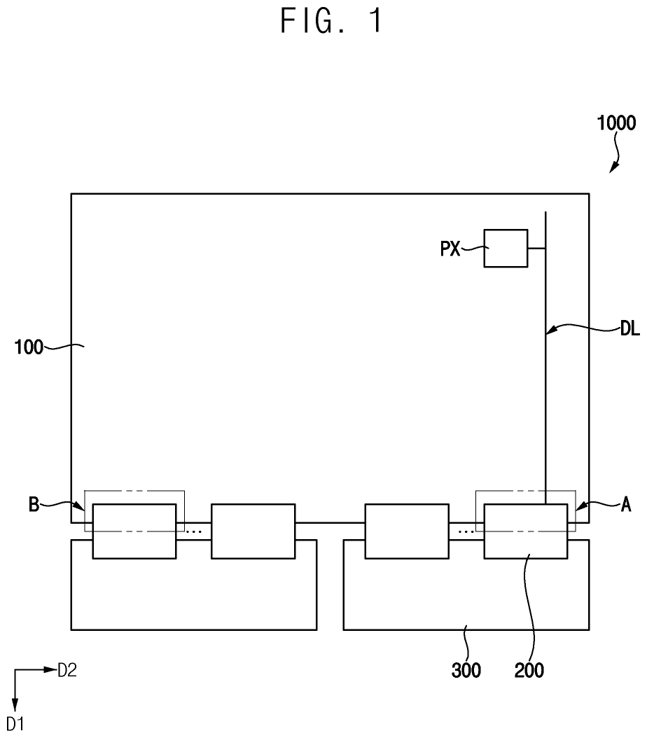

FIG. 1 is a plan view showing a display device, according to an embodiment.

Referring to FIG. 1, a display device 1000, according to an embodiment, may include a display panel 100, at least one connection film 200, and at least one printed circuit board 300.

In an embodiment, the printed circuit board 300 may be disposed on one side of the display panel 100. For example, the printed circuit board 300 may be disposed in a first direction D1 from the display panel 100.

In an embodiment, the printed circuit board 300 may be connected to the connecting film 200. The printed circuit board 300 may be electrically connected to the display panel 100 through the connecting film 200.

In an embodiment, the printed circuit board 300 may be disposed on one side of the connection film 200 and may be arranged side by side in a second direction D2 intersecting the first direction D1.

In an embodiment, the connection film 200 may be connected to the display panel 100 and the printed circuit board 300. The connection film 200 may electrically connect the display panel 100 and the printed circuit board 300.

In an embodiment, the connection film 200 may be disposed on one side of the display panel 100 and may be arranged side by side in the second direction D2.

In an embodiment, the display panel 100 may be disposed on one side of the connection film 200. For example, the display panel 100 may be disposed in a direction opposite to the first direction D1 from the connection film 200.

In an embodiment, the display panel 100 may be connected to the connecting film 200. The display panel 100 may be electrically connected to the connection film 200.

In an embodiment, at least one pixel PX may be disposed on the display panel 100. The pixel PX may generate a driving current using a signal and/or a voltage applied through the connection film 200. Also, the pixel PX may emit light corresponding to the driving current. As light is emitted from the pixel PX, the display panel 100 may display an image.

In an embodiment, a data line DL directed in a direction opposite to the first direction D1 may be disposed on the display panel 100. The data line DL is connected to the connection film 200 and the pixel PX, and may provide a data voltage to the pixel PX.

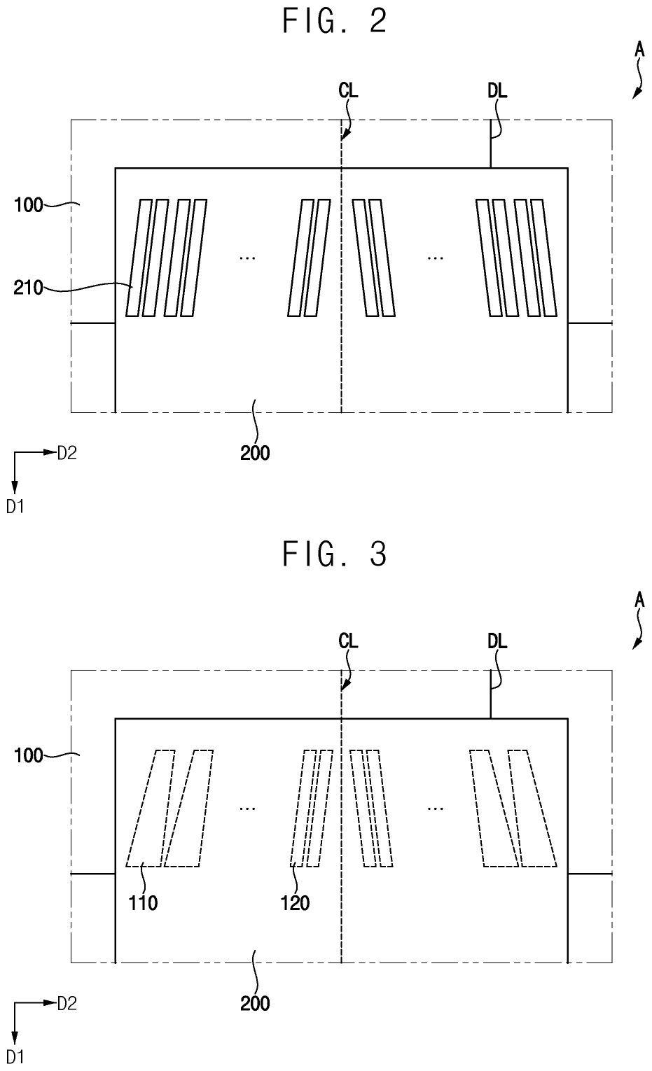

FIG. 2 is a plan view showing connection pads arranged in area A of FIG. 1, according to an embodiment.

In an embodiment and referring to FIG. 2, connection pads 210 may be disposed on one end of the connection film 200. For example, as shown in FIG. 2, the connection pads 210 may be disposed at one end of the connection film 200 that is bonded to the display panel 100.

In an embodiment, a center line CL may be defined at the center of the connection film 200. The center line CL may be an imaginary line passing through the center of the connection film 200 and may extend in the first direction D1.

In an embodiment, the connection pads 210 may be arranged along the second direction D2.

In an embodiment, the connection pads 210 may be disposed symmetrical with respect to the center line CL. For example, as shown in FIG. 2, the connection pads 210 may form a certain angle with the center line CL and may be disposed symmetrical with respect to the center line CL.

However, in other embodiments the invention is not limited thereto. In an embodiment, the connection pads 210 may have various angles with the center line CL. The connection pads 210 may have a shape directed in a direction parallel to the center line CL and may be arranged side by side along the second direction D2. That is, the connection pads 210 may be arranged parallel to the center line CL without forming a certain angle.

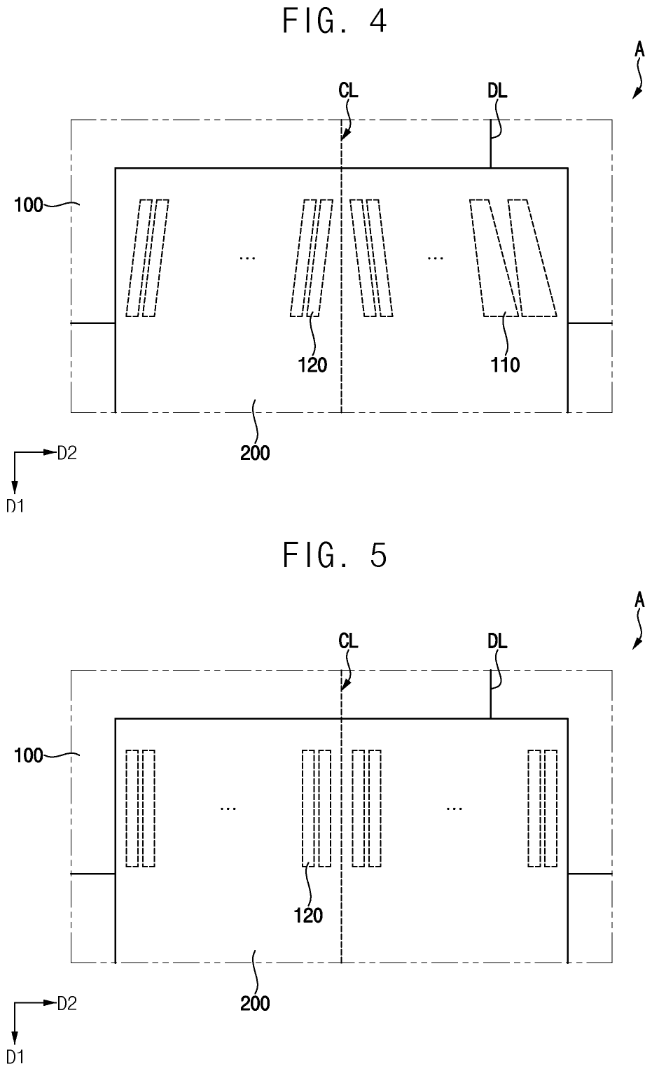

FIG. 3 is a plan view showing an example of signal pads arranged in area A of FIG. 1, according to an embodiment. FIG. 4 is a plan view showing another example of signal pads arranged in area A of FIG. 1, according to an embodiment. FIG. 5 is a plan view showing still another example of signal pads arranged in area A of FIG. 1, according to an embodiment.

In an embodiment and referring to FIGS. 3 to 5, signal pads may be disposed on one end of the display panel 100. The signal pads may include first signal pads 110 and second signal pads 120. The first signal pads 110 and the second signal pads 120 may be disposed at one end of the display panel 100 that is bonded to the connection film 200. The first signal pads 110 and the second signal pads 120 may be arranged along the second direction D2.

In an embodiment, the first signal pads 110 may transmit power voltage to the display panel 100. The power voltage may be a VDD signal or a VSS signal.

In an embodiment, the second signal pads 120 may transmit data voltage to the display panel 100. The data voltage may be transmitted along the data line DL.

In an embodiment, a planar area of the first signal pad 110 may be larger than a planar area of the second signal pad 120. Specifically, a width of the first signal pad 110 in the second direction D2 may be larger than a width of the second signal pad 120 in the second direction D2. A width of the first signal pad 110 in the first direction D1 may be substantially the same as a width of the second signal pad 120 in the first direction D1. However, the invention is not limited thereto.

In an embodiment, the connection pads 210 disposed on the left and right with respect to the center line CL may be symmetrical with respect to the center line CL. Additionally, the first signal pads 110 disposed on the left and right with respect to the center line CL may be symmetrical with respect to the center line CL. Additionally, the second signal pads 120 disposed on the left and right with respect to the center line CL may be symmetrical with respect to the center line CL. However, embodiments of the invention are not limited thereto.

In an embodiment and as shown in FIG. 4, the first signal pads 110 may not be symmetrical with respect to the center line CL. For example, the first pads 110 may be disposed in the second direction D2 with respect to the center line CL, but the first pads 110 may not be disposed in the opposite direction to the second direction D2 with respect to the center line CL. However, the invention is not limited to this embodiment.

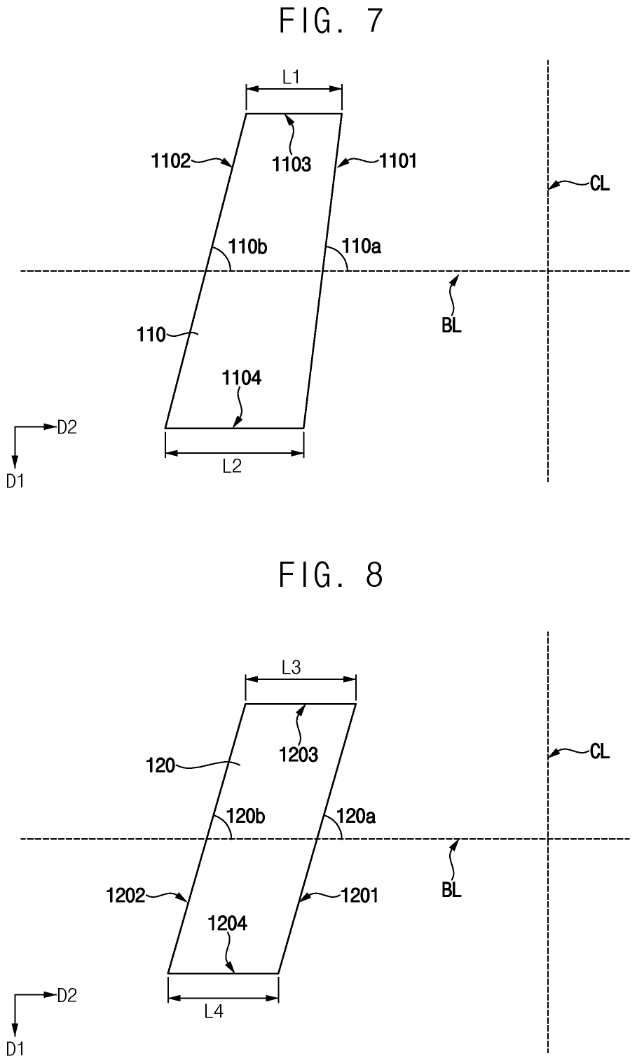

In an embodiment, the first signal pad 110 and the second signal pad 120 may include various angles with the center line CL. For example, one side of the first signal pad 110 and the second signal pad 120 directed along the first direction D1 may include an angle ranging from about 0 degrees to about 90 degrees with the center line CL. Details will be described later in FIGS. 7 to 9.

In an embodiment, the second signal pads 120 may be disposed closer to the center line CL than the first signal pads 110. That is, the second signal pads 120 may be disposed farther inside the connection film 200 than the first signal pads 110.

In an embodiment and as shown in FIG. 5, the first signal pad 110 may not be disposed in area A. That is, only the second signal pad 120 may be disposed in area A. If the first signal pad 110 is not placed in area A, the first signal pad 110 may be placed in area B, which will be described later.

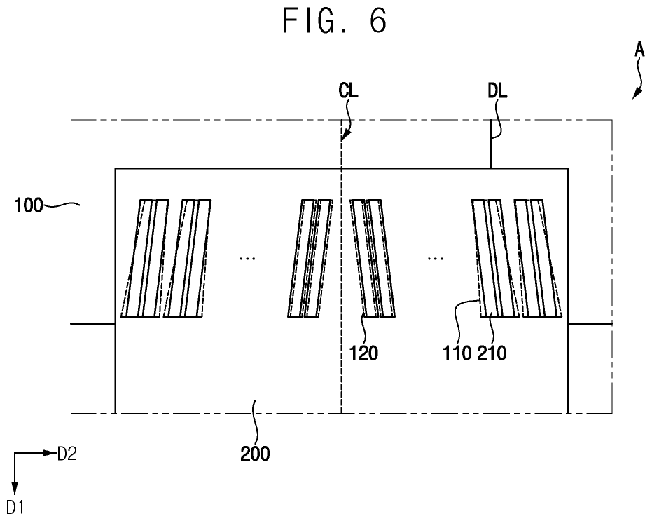

FIG. 6 is a plan view showing the connection pads of FIG. 2 and the signal pads of FIG. 3 overlapping in area A of FIG. 1, according to an embodiment.

In an embodiment and referring to FIG. 6, the first signal pads 110 and the connection pads 210 may overlap on a plane.

In an embodiment, a planar area of the first signal pad 110 may be larger than a planar area of the connection pad 210.

In an embodiment, a width of the first signal pad 110 in the second direction D2 may be larger than a width of the connection pad 210 in the second direction D2. A width of the first signal pad 110 in the first direction D1 may be substantially the same as a width of the connection pad 210 in the first direction D1. However, the invention is not limited thereto.

In an embodiment, each of the first signal pads 110 may overlap at least two of the connection pads 210 on a plane. For example, as shown in FIG. 6, some of the connection pads 210 corresponding to one of the first signal pads 110 may partially overlap with the first signal pad 110, and some may entirely overlap with the first signal pad 110 on a plane.

However, the invention is not limited to this, and in another embodiment, the connection pad 210 corresponding to any one of the first signal pads 110 may entirely overlap with the first signal pad 110 on a plane. That is, all of the connection pads 210 corresponding to one of the first signal pads 110 may entirely overlap the first signal pad 110 on a plane.

In an embodiment and as shown in FIG. 6, the second signal pads 120 and the connection pads 210 may overlap on a plane.

In an embodiment, a planar area of the second signal pad 120 may be substantially the same as a planar area of the connection pad 210.

In an embodiment, a width of the second signal pad 120 in the second direction D2 may be substantially the same as a width of the connection pad 210 in the second direction D2. A width of the second signal pad 120 in the first direction D1 may be substantially the same as a width of the connection pad 210 in the first direction D1. That is, the second signal pad 120 may have substantially the same shape and size as the connection pad 210. However, the invention is not limited thereto.

In an embodiment, the second signal pads 120 may overlap the connection pads 210 in a one-to-one correspondence. For example, as shown in FIG. 6, the connection pad 210 corresponding to one of the second signal pads 120 may partially overlap the second signal pad 120 on a plane.

However, the invention is not necessarily limited to this, and in another embodiment, the connection pad 210 corresponding to any one of the second signal pads 120 may entirely overlap with the second signal pad 120 on a plane.

FIG. 7 is an enlarged plan view of a first signal pad included in the signal pads of FIG. 3, according to an embodiment. For example, FIG. 7 may show one of the first signal pads 110 disposed to the left of the center line CL of FIG. 3. Meanwhile, the first signal pads 110 disposed on the left and right with respect to the center line CL in FIG. 3 may be disposed symmetrical with respect to the center line CL. Hereinafter, the description will focus on the first signal pad 110 disposed to the left of the center line CL in FIG. 3.

In an embodiment and referring to FIG. 7, the first signal pad 110 may include a first side 1101, a second side 1102, a third side 1103, and a fourth side 1104.

In an embodiment, the first side 1101 and the second side 1102 may face each other. For example, the first side 1101 and the second side 1102 may face each other in the second direction D2. The first side 1101 may be disposed closer to the center line CL than the second side 1102. That is, the first side 1101 may be disposed farther inside the connecting film 200 than the second side 1102.

In an embodiment, the first side 1101 may have a first inclination angle 110a on a plane with respect to the reference line BL.

In an embodiment, the reference line BL may be an imaginary line directed in the second direction D2. That is, the reference line BL may be an imaginary line directed parallel to the second direction D2.

In addition, in an embodiment, the first inclination angle 110a may be defined as an angle rotated counterclockwise with respect to the reference line BL, among angles formed by the first side 1101 of the first signal pad 110 with respect to the reference line BL. Conversely, in the case of the first signal pad 110 disposed on the right side of the center line CL, the first inclination angle 110a may be defined as an angle rotated clockwise with respect to the reference line BL.

In an embodiment, the second side 1102 may have a second inclination angle 110b on a plane with respect to the reference line BL.

In an embodiment, the second inclination angle 110b may be defined as an angle rotated counterclockwise with respect to the reference line BL, among angles formed by the second side 1102 of the first signal pad 110 with respect to the reference line BL. Conversely, in the case of the first signal pad 110 disposed on the right side of the center line CL, the second inclination angle 110b may be defined as an angle rotated clockwise with respect to the reference line BL.

In an embodiment, the first inclination angle 110a and the second inclination angle 110b may be different. For example, the first inclination angle 110a may be larger than the second inclination angle 110b.

In an embodiment, the third side 1103 and the fourth side 1104 may face each other. For example, the third side 1103 and the fourth side 1104 may face each other in the first direction D1. The fourth side 1104 may be disposed closer to the printed circuit board (e.g. printed circuit board 300 of FIG. 1) than the third side 1103.

In an embodiment, the third side 1103 and the fourth side 1104 may be directed parallel to the reference line BL. However, the invention is not limited thereto.

In an embodiment, the third side 1103 and the fourth side 1104 may connect the first side 1101 and the second side 1102.

In an embodiment, the third side 1103 may have a first length L1 directed along the second direction D2. The first length L1 may be defined as the length of one line connecting the point where the third side 1103 intersects the first side 1101 and the point where the third side 1103 intersects the second side 1102.

In an embodiment, the fourth side 1104 may have a second length L2 directed along the second direction D2. The second length L2 may be defined as the length of one line connecting the point where the fourth side 1104 intersects the first side 1101 and the point where the fourth side 1104 intersects the second side 1102.

In an embodiment, the first length L1 and the second length L2 may be different. For example, the second length L2 may be longer than the first length L1. In other words, as the first side 1101 has the first inclination angle 110a and the second side 1102 has a second inclination angle 110b that is smaller than the first inclination angle 110a, the second length L2 may be longer than the first length L1.

In an embodiment, a width of the first signal pad 110 in the second direction D2 may vary from the third side 1103 to the fourth side 1104. For example, a width of the first signal pad 110 in the second direction D2 may increase from the third side 1103 to the fourth side 1104. However, the invention is not limited to this, and if the second length L2 is longer than the first length L1, a width of the first signal pad 110 in the second direction D2 may change in various ways as moving from the third side 1103 to the fourth side 1104. For example, a width of the first signal pad 110 in the second direction D2 may be constant from the third side 1103 to the fourth side 1104 and then may increase from a specific point. In still another example, a width of the first signal pad 110 in the second direction D2 may increase from the third side 1103 to the fourth side 1104 and then may become constant from a specific point.

FIG. 8 is an enlarged plan view of a second signal pad included in the signal pads of FIG. 3, according to an embodiment.

In an embodiment, the second signal pads 120 disposed on the left and right with respect to the center line CL in FIG. 8 may be disposed symmetrical with respect to the center line CL, Hereinafter, the description will focus on the second signal pad 120 disposed to the left of the center line CL in FIG. 6.

In an embodiment and referring to FIG. 8, the second signal pad 120 may include a fifth side 1201, a sixth side 1202, a seventh side 1203, and an eighth side 1204.

In an embodiment, the fifth side 1201 and the sixth side 1202 may face each other. For example, the fifth side 1201 and the sixth side 1202 may face each other in the second direction D2. The fifth side 1201 may be disposed closer to the center line CL than the sixth side 1202. That is, the fifth side 1201 may be disposed farther inside the connection film 200 than the sixth side 1202.

In an embodiment, the fifth side 1201 may have a third inclination angle 120a on a plane with respect to the reference line BL.

In an embodiment, the third inclination angle 120a may be defined as an angle rotated counterclockwise with respect to the reference line BL, among angles formed by the fifth side 1201 of the second signal pad 120 with respect to the reference line BL. Conversely, in the case of the second signal pad 120 disposed on the right side of the center line CL, the third inclination angle 120a may be defined as an angle rotated clockwise with respect to the reference line BL.

In an embodiment, the sixth side 1202 may have a fourth inclination angle 120b on a plane with respect to the reference line BL.

In an embodiment, the fourth inclination angle 120b may be defined as an angle rotated counterclockwise with respect to the reference line BL, among angles formed by the sixth side 1202 of the second signal pad 120 with respect to the reference line BL. Conversely, in the case of the second signal pad 120 disposed on the right side of the center line CL, the fourth inclination angle 120b may be defined as an angle rotated clockwise with respect to the reference line BL.

In an embodiment, the third inclination angle 120a and the fourth inclination angle 120b may be the same. That is, the fifth side 1201 and the sixth side 1202 may be directed parallel to each other.

In an embodiment, the seventh side 1203 and the eighth side 1204 may face each other. For example, the seventh side 1203 and the eighth side 1204 may face each other in the first direction D1. The eighth side 1204 may be disposed closer to the printed circuit board (e.g. printed circuit board 300 of FIG. 1) than the seventh side 1203.

In an embodiment, the seventh side 1203 and the eighth side 1204 may be directed parallel to the reference line BL. However, the invention is not limited thereto.

In an embodiment, the seventh side 1203 and the eighth side 1204 may connect the fifth side 1201 and the sixth side 1202.

In an embodiment, the seventh side 1203 may have a third length L3 directed along the second direction D2. The third length L3 may be defined as the length of one line connecting the point where the seventh side 1203 intersects the fifth side 1201 and the point where the seventh side 1203 intersects the sixth side 1202.

In an embodiment, the eighth side 1204 may have a fourth length LA directed along the second direction D2. The fourth length LA may be defined as the length of one line connecting the point where the eighth side 1204 intersects the fifth side 1201 and the point where the eighth side 1204 intersects the sixth side 1202.

In an embodiment, the third length L3 may be the same as the fourth length LA. In other words, as the fifth side 1201 has the third inclination angle 120a and the sixth side 1202 has the fourth inclination angle 120b same to the third inclination angle 120a, the third length L3 may be the same as the fourth length L4.

According to embodiments, each of the first signal pads 110 may overlap at least two of the connection pads 210 on a plane. That is, a contact area between the connection pads 210 and the first signal pads 110 may increase. The resistance difference between the connection pads 210 and the signal pads 110 may be reduced. Accordingly, heat generation of the display device (e.g. display device 1000 of FIG. 1) may be reduced or prevented. Additionally, alignment error between the connection pads 210 and the first signal pads 110 may be reduced. Accordingly, the reliability of the display device may be improved.

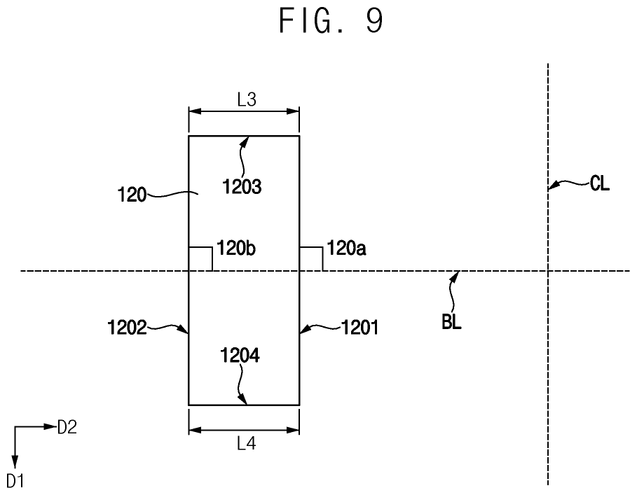

FIG. 9 is an enlarged plan view of a second signal pad included in the signal pads of FIG. 5, according to an embodiment.

In an embodiment, the second signal pad 120 described with reference to FIG. 9 may be substantially the same as the second signal pad 120 described in FIG. 8 except for the third inclination angle 120a and the fourth inclination angle 120b. Therefore, overlapping explanations may be omitted or simplified.

In an embodiment and referring to FIG. 9 the second signal pad 120 may extend in a direction parallel to the center line CL.

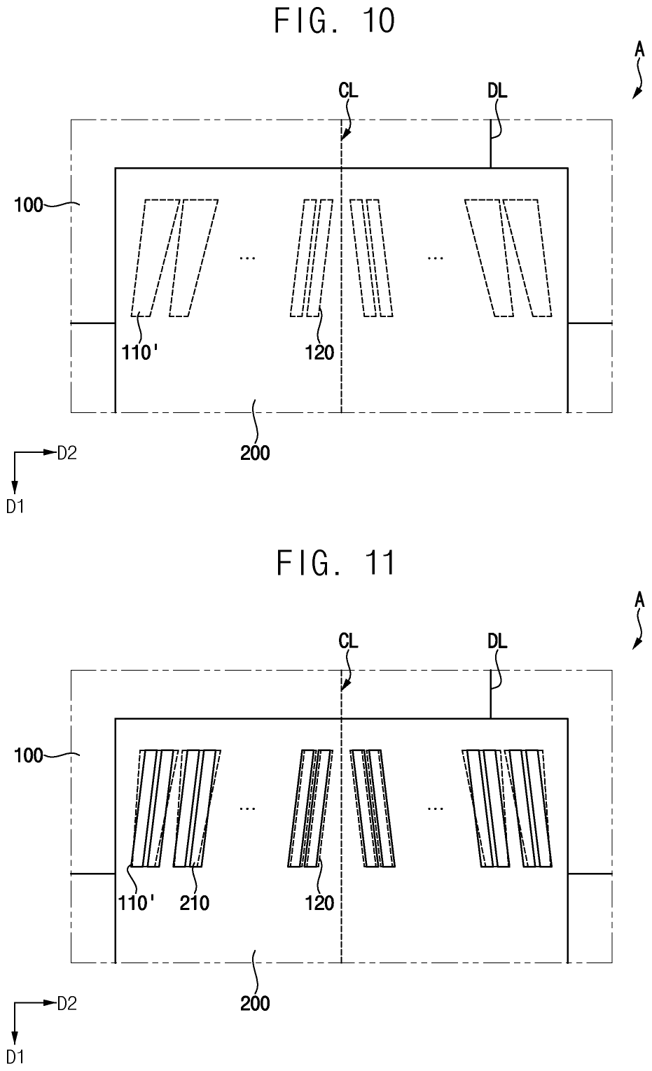

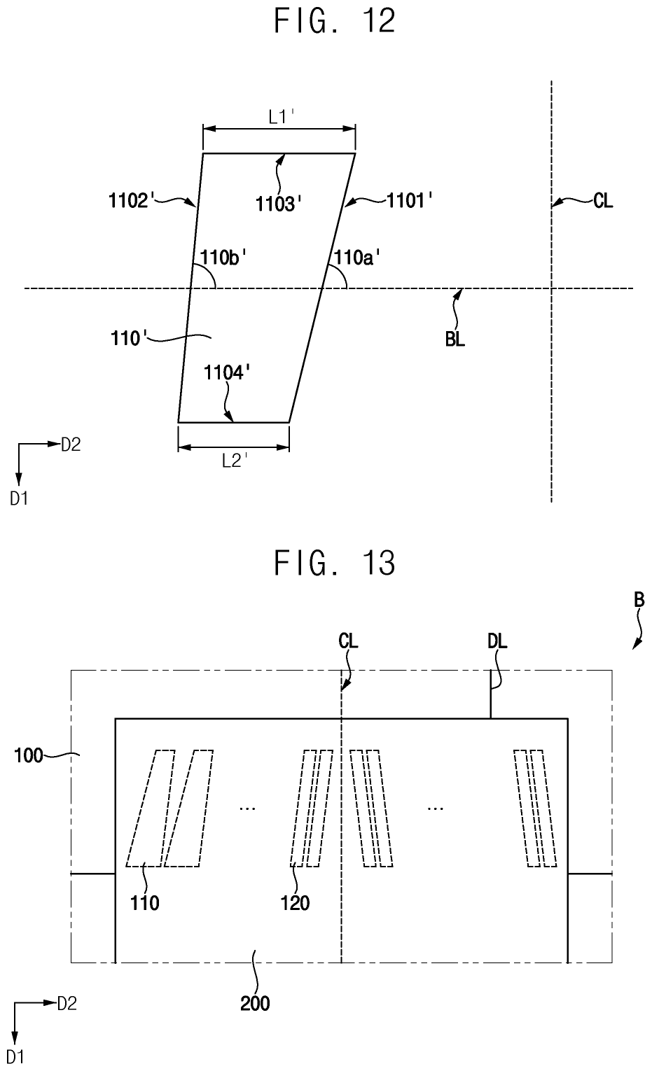

FIG. 10 is a plan view showing still another example of signal pads arranged in area A of FIG. 1, according to an embodiment. FIG. 11 is a plan view showing the connection pads of FIG. 2 and the signal pads of FIG. 10 overlapping in area A of FIG. 1, according to an embodiment. FIG. 12 is an enlarged plan view showing the first signal pad included in the signal pads of FIG. 10, according to an embodiment.

In an embodiment and referring to FIGS. 10 to 12, the signal pads shown in FIGS. 10 to 12 may be the same as the signal pads shown in FIGS. 3 to 7 except for including a first signal pad 110′ instead of the first signal pad 110. That is, the first signal pad 110′ of FIGS. 10 to 12 may be the same as the first signal pad 110 of FIGS. 3 to 7 except for the shape. Accordingly, overlapping descriptions may be omitted or simplified.

In an embodiment and as shown in FIG. 10, the first signal pads 110′ and the second signal pads 120 may be disposed at one end of the display panel 100.

In an embodiment, the first signal pads 110′ and the second signal pads 120 may be disposed at one end of the display panel 100 that is bonded to the connection film 200. Specifically, the first signal pads 110′ and the second signal pads 120 may be arranged side by side along the second direction D2.

In an embodiment, a planar area of the first signal pad 110′ may be larger than a planar area of the second signal pad 120.

In an embodiment, a width of the first signal pad 110′ in the second direction D2 may be larger than a width of the second signal pad 120 in the second direction D2. A width of the first signal pad 110′ in the first direction D1 may be substantially the same as a width of the second signal pad 120 in the first direction D1. However, the invention is not limited thereto.

In an embodiment, as shown in FIG. 11, the first signal pads 110′ and the connection pads 210 may overlap.

In an embodiment, a planar area of the first signal pad 110′ may be larger than a planar area of the connection pad 210.

In an embodiment, a width of the first signal pad 110′ in the second direction D2 may be larger than a width of the connection pad 210 in the second direction D2. A width of the first signal pad 110′ in the first direction D1 may be substantially the same as a width of the connection pad 210 in the first direction D1. However, the invention is not limited thereto.

In an embodiment, each of the first signal pads 110′ may overlap at least two of the connection pads 210 in a plan view. For example, as shown in FIG. 11, some of the connection pads 210 corresponding to any one of the first signal pads 110′ may partially overlap the first signal pad 110′ in a plan view, and others may entirely overlap the first signal pad 110′ in a plan view.

However, the invention is not limited to this, and in another embodiment, the connection pad 210 corresponding to any one of the first signal pads 110′ may entirely overlap with the first signal pad 110′ on a plane. That is, all of the connection pads 210 corresponding to one of the first signal pads 110′ may entirely overlap the first signal pad 110′ on a plane.

In an embodiment and as shown in FIG. 12, the first signal pad 110′ may include a first side 1101′, a second side 1102′, a third side 1103′, and a fourth side 1104′.

In an embodiment, the first side 1101′ and the second side 1102′ may face each other. For example, the first side 1101′ and the second side 1102′ may face each other in the second direction D2. The first side 1101′ may be disposed closer to the center line CL than the second side 1102′. That is, the first side 1101′ may be disposed farther inside the connection film 200 rather than the second side 1102′.

In an embodiment, the first side 1101′ may have a first inclination angle 110a′ on a plane with respect to the reference line BL.

In an embodiment, the first inclination angle 110a′ may be defined as an angle rotated counterclockwise with respect to the reference line BL, among angles formed by the first side 1101′ of the first signal pad 110′ with respect to the reference line BL. Conversely, in the case of the first signal pad 110′ disposed on the right side of the center line CL, the first inclination angle 110a′ may be defined as an angle rotated clockwise with respect to the reference line BL.

In an embodiment, the second side 1102′ may have a second inclination angle 110b′ on a plane with respect to the reference line BL.

In an embodiment, the second inclination angle 110b′ may be defined as an angle rotated counterclockwise with respect to the reference line BL, among angles formed by the second side 1102′ of the first signal pad 110′ with respect to the reference line BL. Conversely, in the case of the first signal pad 110′ disposed on the right side of the center line CL, the second inclination angle 110b′ may be defined as an angle rotated clockwise with respect to the reference line BL.

In an embodiment, the first inclination angle 110a′ and the second inclination angle 110b′ may be different. For example, the first inclination angle 110a′ may be smaller than the second inclination angle 110b′.

In an embodiment, the third side 1103′ and the fourth side 1104′ may face each other. For example, the third side 1103′ and the fourth side 1104′ may face each other in the first direction D1. The fourth side 1104′ may be disposed closer to the printed circuit board (e.g. printed circuit board 300 of FIG. 1) than the third side 1103′.

In an embodiment, the third side 1103′ and the fourth side 1104′ may be parallel to the reference line BL. However, the invention is not limited thereto.

In an embodiment, the third side 1103′ and the fourth side 1104′ may connect the first side 1101′ and the second side 1102′.

In an embodiment, the third side 1103′ may have a first length L1′ along the second direction D2. The first length L1′ may be defined as the length of one line connecting the intersecting points where the third side 1103′ intersects the first side 1101′ and the point where the third side 1103′ intersects the second side 1102′.

In an embodiment, the fourth side 1104′ may have a second length L2′ along the second direction D2. The second length L2′ may be defined as the length of one line connecting the intersecting points where the fourth side 1104′ intersects the first side 1101′ and the fourth side 1104′ intersects the second side 1102′.

In an embodiment, the first length L1′ and the second length L2′ may be different. For example, the second length L2′ may be shorter than the first length L1′. In other words, as the first side 1101′ has the first inclination angle 110a′, and the second side 1102′ has a second inclination angle 110b′ which is larger than the first inclination angle 110a′, the first length L1′ may be larger than the second length L2′.

In an embodiment, a width of the first signal pad 110′ in the second direction D2 may vary from the third side 1103′ to the fourth side 1104′. For example, a width of the first signal pad 110′ in the second direction D2 may decrease from the third side 1103′ to the fourth side 1104′. However, the invention is not limited to this, and if the first length L1′ is longer than the second length L2′, a width of the first signal pad 110′ in the second direction D2 may change in various ways as moving from the third side 1103′ to the fourth side 1104′. For another example, a width of the first signal pad 110′ in the second direction D2 may be constant from the third side 1103′ to the fourth side 1104′ and then may decrease from a certain point. For still another example, a width of the first signal pad 110′ in the second direction D2 decreases from the third side 1103′ to the fourth side 1104′ and becomes constant from a certain point.

FIG. 13 is a plan view showing signal pads arranged in area B of FIG. 1, according to an embodiment.

Configurations described with reference to FIG. 13 may be substantially the same as those described in FIGS. 3 to 5, except for the shape of the first signal pad 110 in FIGS. 3 to 5. Therefore, overlapping explanations may be omitted or simplified. In an embodiment, the first signal pads 110 disposed in the area B may have a shape in which the third side 1103′ is longer than the fourth side 1104′, as shown in FIGS. 10 to 12. To put it simply, the first signal pad 110 and the second signal pad 120 that may be arranged in the area B may be different from those shown in FIGS. 2 to 12 except for the shape of the first signal pad 110.

According to embodiments, each of the first signal pads 110 may overlap at least two of the connection pads 210 on a plane. That is, a contact area between the connection pads 210 and the first signal pads 110 may increase. Accordingly, a resistance difference between the connection pads 210 and the first signal pads 110 may be reduced. Accordingly, heat generation of the display device (e.g. display device 1000 of FIG. 1) may be reduced or prevented. Additionally, alignment error between the connection pads 210 and the first signal pads 110 may be reduced. Accordingly, the reliability of the display device may be improved.

The invention should not be construed as being limited to the embodiments set forth herein. Rather, these embodiments are provided so that this disclosure will be thorough and complete and will fully convey the invention to those skilled in the art. And, while the invention has been particularly shown and described with reference to embodiments thereof, it will be understood by those of ordinary skill in the art that various changes in form and details may be made therein without departing from the spirit or scope of the invention. Moreover, the embodiments or parts of the embodiments may be combined in whole or in part without departing from the scope of the invention.

What is claimed is:

1. A display device comprising:
a display panel that displays images;
a printed circuit board driving the display panel and disposed in a first direction relative to the display panel;
a connecting film electrically connecting the display panel and the printed circuit board;
connection pads disposed at one end of the connection film bonded to the display panel and directed along a second direction intersecting the first direction; and
first signal pads disposed on the display panel and directed along the second direction, transmitting a power voltage, and overlapping with at least two of the connection pads on a plane.

2. The display device of claim 1, wherein a planar area of each of the first signal pads is larger than a planar area of each of the connection pads.

3. The display device of claim 1, wherein each of the first signal pads includes:
a first side having a first inclination angle on a plane with respect to a reference line directed in the second direction; and
a second side facing the first side and having a second inclination angle on a plane with respect to the reference line, wherein the second inclination angle is different from the first inclination angle.

4. The display device of claim 3, wherein each of the first signal pads further includes:
a third side connecting the first side and the second side and having a first length; and
a fourth side facing the third side and being disposed closer to the printed circuit board than the third side, wherein the fourth side includes a second length which is different from the first length.

5. The display device of claim 4, wherein a width of each of the first signal pads directed in the second direction changes from the third side to the fourth side.

6. The display device of claim 4, wherein the second inclination angle is larger than the first inclination angle, and
wherein the first length is longer than the second length.

7. The display device of claim 6, wherein a width of each of the first signal pads in the second direction decreases from the third side to the fourth side.

8. The display device of claim 4, wherein the second inclination angle is smaller than the first inclination angle, and
wherein the first length is shorter than the second length.

9. The display device of claim 8, wherein a width of each of the first signal pads directed in the second direction increases from the third side to the fourth side.

10. The display device of claim 3, further comprising:
second signal pads disposed on the display panel and directed along the second direction, transmitting a data voltage, and overlapping with one of the connection pads on a plane,
wherein each of the second signal pads includes:
a fifth side having a third inclination angle on a plane with respect to the reference line;
a sixth side facing the fifth side and having a fourth inclination angle, wherein the fourth inclination angle is the same as the third inclination angle on a plane with respect to the reference line;
a seventh side connecting the fifth side and the sixth side and having a third length; and
an eighth side facing the seventh side disclosed closer to the printed circuit board than the seventh side, wherein the eighth side includes a fourth length which is the same as the third length.

11. The display device of claim 10, wherein a width of each of the second signal pads directed in the second direction is constant from the seventh side to the eighth side.

12. The display device of claim 10, wherein a planar area of each of the first signal pads is larger than a planar area of each of the second signal pads.

13. The display device of claim 10, wherein the second signal pads overlap the connection pads in a one-to-one correspondence.

14. The display device of claim 13, wherein one or more of the connection pads corresponding to one of the first signal pads partially overlap the one of the first signal pads on a plane.

15. The display device of claim 13, wherein the connection pads corresponding to one of the first signal pads entirely overlap the one of the first signal pads on a plane.

16. A display device comprising:
a display panel that displays images; and
first signal pads disposed on the display panel and directed along one direction and transmitting a power voltage,
wherein each of the first signal pads includes:
a first side having a first inclination angle on a plane with respect to a reference line directed in the one direction; and
a second side facing the first side and having a second inclination angle on a plane with respect to the reference line, wherein the second inclination angle is different from the first inclination angle.

17. The display device of claim 16, wherein each of the first signal pads further includes:
a third side connecting the first side and the second side and having a first length; and
a fourth side facing the third side, wherein the fourth side is disposed closer to the printed circuit board than the third side, and includes a second length which is different from the first length.

18. The display device of claim 17, wherein a width of each of the first signal pads directed in the one direction changes from the third side to the fourth side.

19. The display device of claim 18, wherein a width of each of the first signal pads directed in the one direction decreases from the third side to the fourth side.

20. The display device of claim 18, wherein a width of each of the first signal pads directed in the one direction increases from the third side to the fourth side.
